(19) United States
(12) Patent Application Publication
(10) Pub. No.: US 2021/0083008 A1
(43) Pub. Date: Mar. 18, 2021

(54) SEMICONDUCTOR STORAGE DEVICE

(71) Applicant: KIOXIA CORPORATION, Tokyo (JP)

(72) Inventor: Yusuke KOBAYASHI, Kuwana Mie (JP)

(73) Assignee: KIOXIA CORPORATION, Tokyo (JP)

(21) Appl. No.: 17/010,392

(22) Filed: Sep. 2, 2020

(30) Foreign Application Priority Data
Sep. 17, 2019 (JP) 2019-168164

(51) Int. Cl. H01L 27/24; H01L 45/00

(52) U.S. Cl. CPC H01L 27/2481; H01L 27/2427; H01L 45/144; H01L 45/1675; H01L 45/06

(57) ABSTRACT

A semiconductor storage device includes a first wiring, a second wiring, an insulating film, a variable resistance film, and an insulating portion. The first wiring extends in a first direction. The second wiring extends in a second direction intersecting the first direction and is provided at a position different from the first wiring in a third direction intersecting the first direction and the second direction. The insulating film is provided between the first wiring and the second wiring in the third direction. The variable resistance film is provided between the first wiring and the second wiring in the third direction and is adjacent to the insulating film in the first direction. The insulating portion includes a portion provided between the first wiring and the second wiring in the third direction and is adjacent to the first insulating film from a side opposite to the variable resistance film.

### CROSS-REFERENCE TO RELATED APPLICATION(S)

This application is based upon and claims the benefit of priority from Japanese Patent Application No. 2019-168164, filed Sep. 17, 2019, the entire contents of which are incorporated herein by reference.

### FIELD

Embodiments described herein relate generally to a semiconductor storage device.

### BACKGROUND

As an example of a storage class memory (SCM), a semiconductor storage device having a cross-point structure using a phase-change memory (PCM) is known.

Examples of related art include JP-A-2011-40579.

### DESCRIPTION OF THE DRAWINGS

FIG. 1 is a schematic perspective view of a semiconductor storage device according to a first embodiment.

FIG. 2 is a perspective view of a memory cell according to the first embodiment.

FIG. 3 is a cross-sectional view of a plurality of memory cells according to the first embodiment.

FIG. 4 is a cross-sectional view showing an example of a manufacturing process of the plurality of memory cells according to the first embodiment.

FIG. 5 is a cross-sectional view showing an example of the manufacturing process of the plurality of memory cells according to the first embodiment.

FIG. 6 is a cross-sectional view showing an example of the manufacturing process of the plurality of memory cells according to the first embodiment.

FIG. 7 is a cross-sectional view showing an example of the manufacturing process of the plurality of memory cells according to the first embodiment.

FIG. 8 is a cross-sectional view showing an example of the manufacturing process of the plurality of memory cells according to the first embodiment.

FIG. 9 is a cross-sectional view showing an example of the manufacturing process of the plurality of memory cells according to the first embodiment.

FIG. 10 is a cross-sectional view showing an example of the manufacturing process of the plurality of memory cells according to the first embodiment.

FIG. 11 is a cross-sectional view showing an example of the manufacturing process of the plurality of memory cells according to the first embodiment.

FIG. 12 is a cross-sectional view showing an example of the manufacturing process of the plurality of memory cells according to the first embodiment.

FIG. 13 is a cross-sectional view showing an example of the manufacturing process of the plurality of memory cells according to the first embodiment.

FIG. 14 is a cross-sectional view showing an example of the manufacturing process of the plurality of memory cells according to the first embodiment.

FIG. 15 is a cross-sectional view showing an example of the manufacturing process of the plurality of memory cells according to the first embodiment.

FIG. 16 is a cross-sectional view of a plurality of memory cells according to a second embodiment.

### DETAILED DESCRIPTION

At least one embodiment provides a semiconductor storage device capable of improving electric characteristics.

In general, according to at least one embodiment, a semiconductor storage device includes a first wiring, a second wiring, an insulating film, a variable resistance film, and an insulating portion. The first wiring extends in a first direction. The second wiring extends in a second direction intersecting the first direction and is provided at a position different from the first wiring in a third direction intersecting the first direction and the second direction. The insulating film is provided between the first wiring and the second wiring in the third direction. The variable resistance film is provided between the first wiring and the second wiring in the third direction and is adjacent to the insulating film in the first direction. The insulating portion includes a portion provided between the first wiring and the second wiring in the third direction and is adjacent to the insulating film from a side opposite to the variable resistance film.

Hereinafter, semiconductor storage devices of embodiments will be described with reference to the drawings. In the following description, configurations having the same or similar functions with each other are denoted by the same reference numerals. Configurations having the same or similar functions with each other may not be repeatedly described. Further, terms “parallel”, “orthogonal”, “the same”, and “equivalent” described in the present specification include a case where the terms refer to “substantially parallel”, “substantially orthogonal”, “substantially the same”, and “substantially equivalent”, respectively.

A term “connection” described in the present specification is not limited to a case of being physically connected, and includes a case of being electrically connected. That is, the term “connection” is not limited to a case where two members are in direct contact with each other, but also includes a case where another member is interposed between the two members. A term “contact” described in the present specification means being in direct contact. Terms “overlap”, “face”, and “adjacent” described in the present specification are not limited to a case where the two members directly face each other or in contact with each other, and include a case where there are members different from the two members between the two members.

### First Embodiment

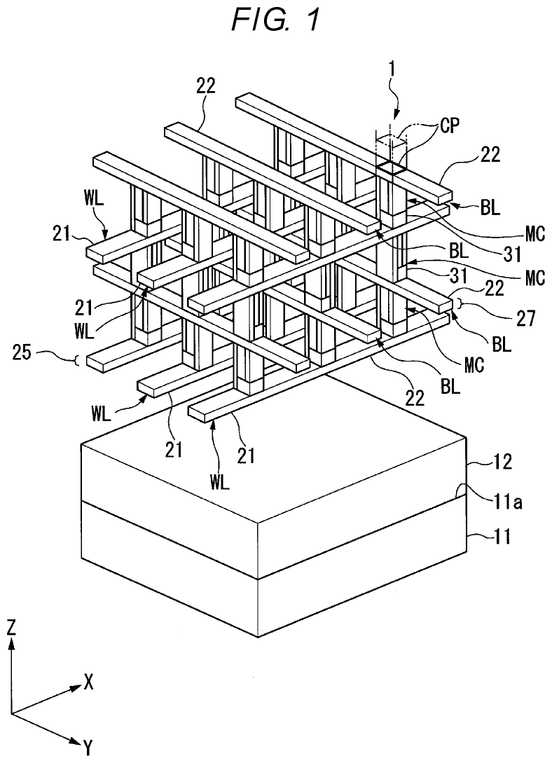

First, a configuration of a semiconductor storage device 1 according to a first embodiment will be described. FIG. 1 is a schematic perspective view of the semiconductor storage device 1. In the following description, an X direction (second direction) is a direction parallel to a surface 11a of a silicon substrate 11, and is a direction in which word lines WLs extend. A Y direction (first direction) is a direction parallel to the surface 11a of the silicon substrate 11, a direction intersecting the X direction, and a direction in which bit lines BLs extend. For example, the Y direction is substantially orthogonal to the X direction. A Z direction (third direction) is a thickness direction of the silicon substrate 11, and is a direction intersecting the X direction and the Y direction. For example, the Z direction is substantially orthogonal to the X direction and the Y direction.

The semiconductor storage device 1 is a so-called cross-point semiconductor storage device using a PCM. The semiconductor storage device 1 includes, for example, the silicon substrate 11, an interlayer insulating layer 12, a plurality of word lines WLs, a plurality of bit lines BLs, and a plurality of memory cells MCs.

On the surface 11a of the silicon substrate 11, a drive circuit (not shown) of the semiconductor storage device 1 is formed. The interlayer insulating layer 12 is formed on the surface 11a of the silicon substrate 11 and covers the drive circuit. The interlayer insulating layer 12 is formed of silicon oxide (SiO₂) or the like.

Each of the plurality of word lines WLs is formed in a band shape in the X direction and extends in the X direction. The plurality of word lines WLs are arranged at intervals in the Y direction and the Z direction. Specifically, the plurality of word lines WLs arranged in the Y direction are at the same position in the Z direction and constitute one word line layer 25. A plurality of word line layers 25 are arranged at intervals in the Z direction. The word lines WLs are formed of tungsten (W) or the like. A word line WL is an example of a “second wiring”. A word line WL adjacent to the word line which is the second wiring in the Y direction is an example of a “third wiring”. A word line WL adjacent to the word line which is the second wiring from a side opposite to the third wiring in the Y direction is an example of a “fourth wiring”.

The plurality of bit lines BLs are formed in a band shape in the Y direction and extend in the Y direction. The plurality of bit lines BLs are arranged at intervals in the X direction and the Z direction. The plurality of bit lines BLs arranged in the X direction are at the same position in the Z direction and constitute one bit line layer 27. The bit line layer 27 is provided between two word line layers 25 adjacent in the Z direction, and is provided at intervals from the two word line layers 25 in the Z direction. A plurality of word line layers 25 and a plurality of bit line layers 27 are alternately arranged one by one in the Z direction. The bit lines BLs are formed of tungsten (W) or the like. A bit line BL is an example of a “first wiring.”

A size of each word line WL in the Y direction and a size of each bit line BL in the X direction are substantially equal to a minimum feature size F of the semiconductor storage device 1. Interlayer insulating layers (not shown in FIG. 1) are interposed between a plurality of adjacent word lines WLs in each word line layer 25 and between a plurality of adjacent bit lines BLs in each bit line layer 27.

When viewed from the Z direction, the word lines WLs and the bit lines BLs intersect with each other. When viewed from the Z direction, the word lines WLs and the bit lines BLs are, for example, orthogonal to each other. When viewed from the Z direction, memory cells MCs are provided in overlapping portions CPs where the word lines WLs and the bit lines BLs overlap. The memory cells MCs are interposed between the word lines WLs and the bit lines BLs in the overlapping portions CPs in the Z direction. That is, the plurality of memory cells MCs are arranged in a three-dimensional matrix at intervals in the X direction, the Y direction, and the Z direction by being provided in the plurality of overlapping portions CPs.

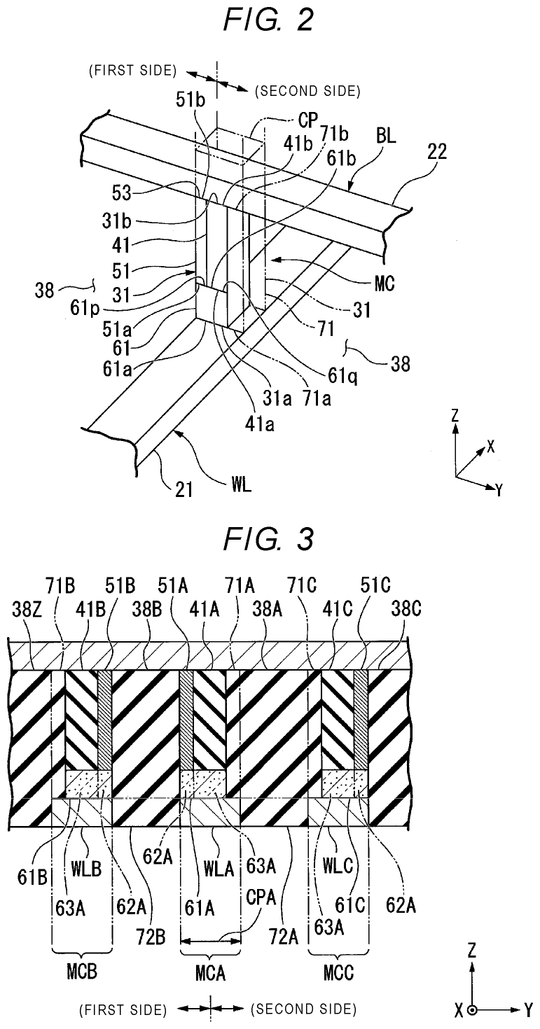

FIG. 2 is a perspective view showing one memory cell MC. As shown in FIG. 2, the memory cell MC includes a pillar 31 having a substantially prismatic shape whose longitudinal direction is the Z direction. One end surface 31a of the pillar is in contact with the word line WL over the entire overlapping portion CP. The other end surface 31b of the pillar 31 is in contact with the bit line BL over the entire overlapping portion CP. It should be noted that an interlayer insulating portion 38 is provided between the memory cells MCs adjacent in the X direction and the Y direction.

The memory cell MC includes, for example, an insulating film 41, a variable resistance film 51, a selector film 61, and an insulating portion 71.

The insulating film 41 is provided between the word line WL and the bit line BL in the Z direction. The insulating film 41 is interposed between the selector film 61 and the bit line BL in the Z direction. That is, one end surface 41a of the insulating film 41 in the Z direction is in contact with the selector film 61. The other end surface 41b of the insulating film 41 in the Z direction is in contact with the bit line BL. The insulating film 41 functions as a hard mask layer of the memory cell MC. The insulating film 41 is formed of silicon nitride (SiN) or the like.

The variable resistance film 51 is provided between the word line WL and the bit line BL in the Z direction, and is interposed between the selector film 61 and the bit line BL in the Z direction. That is, one end surface 51a of the variable resistance film 51 in the Z direction is in contact with the selector film 61. The other end surface 51b of the variable resistance film 51 in the Z direction is in contact with the bit line BL. The variable resistance film 51 is adjacent to the insulating film 41 in the Y direction. The variable resistance film 51 is adjacent to the insulating film 41 only from a first side of the first side and a second side in the Y direction, and is provided only on a first side of the insulating film 41 and on a region of only a first side of the insulating portion 71 in the Y direction. A dimension of the variable resistance film 51 in the Y direction is smaller than a dimension of the selector film 61 in the Y direction, and is, for example, (F/4).

The variable resistance film 51 is formed by the PCM. The variable resistance film 51 is formed of, for example, a chalcogenide alloy of germanium (Ge), antimony (Sb), and tellurium (Te) called GST. A composition ratio of Ge, Sb, and Te is, for example, 2:2:5. The variable resistance film 51 is in a crystalline state and a low resistance state by overheating at a temperature lower than a melting temperature and higher than a crystallization temperature and gradual cooling. The variable resistance film 51 is in an amorphous state and a high resistance state by heating at a temperature equal to or higher than the melting temperature and rapid cooling.

That is, when a current applied to the variable resistance film 51 increases and a voltage reaches a predetermined value, a carrier in the variable resistance film 51 is multiplied and a resistance of the variable resistance film 51 rapidly decreases. When a voltage equal to or higher than the predetermined value is applied to the variable resistance film 51, a large current flows, joule heat is generated, and a temperature of the variable resistance film 51 rises. When the voltage to be applied is controlled and the temperature of the variable resistance film 51 is maintained in a crystallization temperature region, the variable resistance film 51 transits to a polycrystalline state and a resistance of the variable resistance film 51 decreases. When the variable resistance film 51 is in the polycrystalline state, even when the applied voltage is zero, the polycrystalline state is maintained and the resistance of the variable resistance film 51 remains low. When a high voltage is applied to the variable resistance film 51 in the low resistance state, a large current flows, and the temperature of the variable resistance film 51 exceeds a melting point of the chalcogenide alloy or the like. At this time, the chalcogenide alloy of the variable resistance film 51 is melted. When the applied voltage rapidly decreases, the variable resistance film 51 is rapidly cooled, but the resistance of the variable resistance film 51 remains high. In an operation principle of the variable resistance film 51, a state where the resistance of the variable resistance film 51 is lower than a predetermined value is called a “set state”, and a state where the resistance of the variable resistance film 51 is equal to or higher than the predetermined value is called a “reset state.” A rewrite operation for lowering the resistance of the variable resistance film 51 is called a “set operation,” and a rewrite operation for raising the resistance of the variable resistance film 51 is called a “reset operation.”

The variable resistance film 51 is a layer that maintains the low resistance state or the high resistance state described above. A plurality of variable resistance films 51 change their phases and selectively operate the plurality of memory cells MCs. When a voltage is applied or a current is supplied, the variable resistance film 51 can take at least two different resistance values as a bistable state at a room temperature. By writing and reading the two stable resistance values, at least a binary memory operation can be implemented. When the binary memory operation is performed on the variable resistance film 51, for example, the set state of the variable resistance film 51 is set to 1, and the reset state is set to 0.

The selector film 61 is provided between the word line WL and the bit line BL in the Z direction, and is interposed among the word line WL, the insulating film 41, and the variable resistance film 51 in the Z direction. That is, one end surface 61a of the selector film 61 in the Z direction is in contact with the word line WL. A predetermined end surface 61p on a first side of the other end surface 61b of the selector film 61 in the Z direction is in contact with the variable resistance film 51. A predetermined end surface 61q on a second side of the end surface 61b of the selector film 61 is in contact with the insulating film 41. The selector film 61 is adjacent to the insulating portion 71 from the first side in the Y direction, and is provided only on a region of the first side of the insulating portion 71 in the Y direction. The dimension of the selector film 61 in the Y direction is smaller than F, for example, (2F/3).

The selector film 61 is a film functioning as a selection element of the memory cell MC. The selector film 61 may be, for example, a two-terminal switch element. When a voltage applied between the two terminals is equal to or lower than a threshold voltage, the switch element is in a “high resistance” state, for example, an electrically nonconductive state. When the voltage applied between the two terminals is equal to or higher than the threshold voltage, the switch element changes to a “low resistance” state, for example, an electrically conductive state. The switch element may have the function regardless of a polarity of the voltage. The switch element contains at least one chalcogen element selected from a group consisting of tellurium (Te), selenium (Se), and sulfur (S). The switch element may contain a chalcogenide which is a compound containing the chalcogen element. In addition to the above-described elements, the switch element may contain at least one element selected from the group consisting of boron (B), aluminum (Al), gallium (Ga), indium (In), carbon (C), silicon (Si), germanium (Ge), tin (Sn), arsenic (As), phosphorus (P), and antimony (Sb).

The insulating portion 71 is an interlayer insulating layer of the pillar 31, and is a part of the interlayer insulating portion 38. The insulating portion 71 includes a portion provided between the word line WL and the bit line BL in the Z direction, and is substantially the same as a portion provided between one word line WL and one bit line BL in the Z direction. The insulating portion 71 is adjacent to the insulating film 41 from the second side. The second side is an example of a “side opposite to the variable resistance film”. One end surface 71a of the insulating portion 71 in the Z direction is in contact with the word line WL. The other end surface 71b of the insulating portion 71 in the Z direction is in contact with the bit line BL. The insulating portion 71 is formed of silicon oxide (SiO₂) or the like. A material of the insulating portion 71 is the same as a material of the interlayer insulating portion 38.

With relative arrangement of the configurations described above, the end surface 31a of the pillar 31 is constituted by the end surface 61a of the selector film 61 and the end surface 71a of the insulating portion 71 in the Y direction. The end surface 31b of the pillar 31 is constituted by the end surface 41b of the insulating film 41, the end surface 51b of the variable resistance film 51, and the end surface 71b of the insulating portion 71 in the Y direction. The end surfaces 31a and 31b of the pillar 31 substantially match the overlapping portion CP in the X direction and the Y direction.

FIG. 3 is a cross-sectional view showing a plurality of memory cells MCs arranged in the Y direction in the semiconductor storage device 1. As shown in FIG. 3, a memory cell MC is defined as a first memory cell MCA. A memory cell MC that is adjacent to the first memory cell MCA from the first side and sandwiches a second insulating portion 38B with the first memory cell MCA is defined as a second memory cell MCB. A memory cell MC that is adjacent to the first memory cell MCA from the second side which is a side opposite to the first side and sandwiches a first insulating portion 38A with the first memory cell MCA is defined as a third memory cell MCC. Hereinafter, components of the first memory cell MCA are denoted by A at ends of reference numerals of the components thereof. Components of the second memory cell MCB are denoted by B at ends of reference numerals of the components thereof. Components of the third memory cell MCC are denoted by C at ends of reference numerals of the components thereof.

The semiconductor storage device 1 includes, for example, the bit line BL, a word line WLA, a first insulating film 41A, a first variable resistance film 51A, and the first insulating portion 38A. As shown in FIG. 3, the bit line BL is common to the first memory cell MCA, the second memory cell MCB, and the third memory cell MCC, and extends in the Y direction. The word line WLA extends in the X direction and is provided at a position different from the bit line BL in the Z direction. The word line WLA is an example of the “second wiring.”

The first memory cell MCA includes, for example, the first insulating film 41A, the first variable resistance film 51A, a selector film 61A, and the first insulating portion 38A.

The first insulating film 41A is provided between the bit line BL and the word line WLA in the Z direction. The first variable resistance film 51A is provided between the bit line BL and the word line WLA in the Z direction, and is adjacent to the first insulating film 41A in the Y direction. At least a part of the first variable resistance film 51A overlaps with an overlapping portion CPA when viewed in the Z direction. The first insulating portion 38A includes an insulating portion 71A and is adjacent to the first insulating film 41A from the second side. The insulating portion 71A is an example of “a portion provided between the first wiring and the second wiring in the third direction.” The second side is an example of a “side opposite to a first variable resistance film.”

The first variable resistance film 51A is disposed at a position shifted in the Y direction with respect to a center of the word line WLA in the Y direction. The center of the word line WLA in the Y direction is a center that is equidistant from an end of the first side of the word line WLA in the Y direction and an end of the second side which is opposite to the first side in the Y direction. In the arrangement, the first variable resistance film 51A is disposed, for example, between the center of the word line WLA in the Y direction and an edge of the word line WLA in the Y direction. The first variable resistance film 51A is in contact with the first insulating film 41A in the Y direction. The edge of the word line WLA in the Y direction is the end of the first side of the word line WLA in the Y direction, and is an end of the word line WLA that is farthest from the insulating portion 71A in the Y direction.

The first insulating portion 38A is in contact with the first insulating film 41A from the second side. The second side is an example of the “side opposite to the first variable resistance film.” [ 0033] A maximum thickness of the first variable resistance film 51A in the Y direction is smaller than a maximum thickness of the first insulating film 41A in the Y direction. The maximum thickness of the first variable resistance film 51A in the Y direction is equal to or less than half of a maximum width of the word line WLA in 62A and 63A in the Y direction.

A length of the first variable resistance film 51A in the Z direction is larger than maximum thicknesses of the first variable resistance film 51A in the Y direction and the X direction. A length of the first insulating film 41A in the Z direction is larger than a maximum thickness of the first insulating film 41A in the Y direction and the X direction.

The selector film 61A includes the first portion 62A and the second portion 63A. The first portion 62A is provided between one of the bit line BL and the word line WL and the first variable resistance film 51A in the Z direction. The second portion 63A is provided between one of the bit line BL and the word line WL and the first insulating film 41A in the Z direction. The insulating portion 71A is adjacent to the selector film 61A in the Y direction. The insulating portion 71A is an example of “a part of a first insulating portion.”

The maximum thickness of the first variable resistance film 51A in the Y direction is smaller than a maximum thickness of the selector film 61A in the Z direction. The maximum thickness of the first variable resistance film 51A in the Y direction is smaller than the maximum thickness of the selector film 61A in the Z direction.

The semiconductor storage device 1 further includes, for example, a word line WLB, a second insulating film 41B, a second variable resistance film 51B, and a second insulating portion 38Z. The word line WLB is adjacent to the word line WLA from the first side in the Y direction and extends in the X direction. The word line WLB is an example of the “third wiring.” The second insulating film 41B is provided between the bit line BL and the word line WLB in the Z direction. The second variable resistance film 51B is provided between the bit line BL and the word line WLB in the Z direction, and is adjacent to the second insulating film 41B from the second side in the Y direction. The second insulating portion 38Z is adjacent to the second insulating film 41B from the first side in the Y direction. The first side is an example of a “side opposite to a second variable resistance film.”

The first variable resistance film 51A is disposed at a position shifted to the first side in the Y direction with respect to a center portion of the word line WLA in the Y direction. The second variable resistance film 51B is disposed at a position shifted to the second side opposite to the first side in the Y direction with respect to a center portion of the word line WLB in the Y direction.

The semiconductor storage device 1 further includes, for example, a word line WLC, a third insulating film 41C, and a third variable resistance film 51C. The word line WLC is adjacent to the word line WLA from the second side in the Y direction and extends in the X direction. The word line WLC is an example of a “fourth wiring.” The second side is an example of a “side opposite to the third wiring.” The third insulating film 41C is provided between the bit line BL and the word line WLC in the Z direction. The third variable resistance film 51C is provided between the bit line BL and the word line WLC in the Z direction, and is adjacent to the third insulating film 41C from the second side in the Y direction.

The first insulating portion 38A includes an insulating portion 71C provided between the bit line BL and the word line WLC in the Z direction. The insulating portion 71C is an example of “a portion provided between the first wiring and the fourth wiring in the third direction.” The first insulating portion 38A includes an insulating portion 72A provided between the word line WLA and the word line WLC in the Y direction. The second insulating portion 38B includes an insulating portion 72B provided between the word line WLA and the word line WLB in the Y direction.

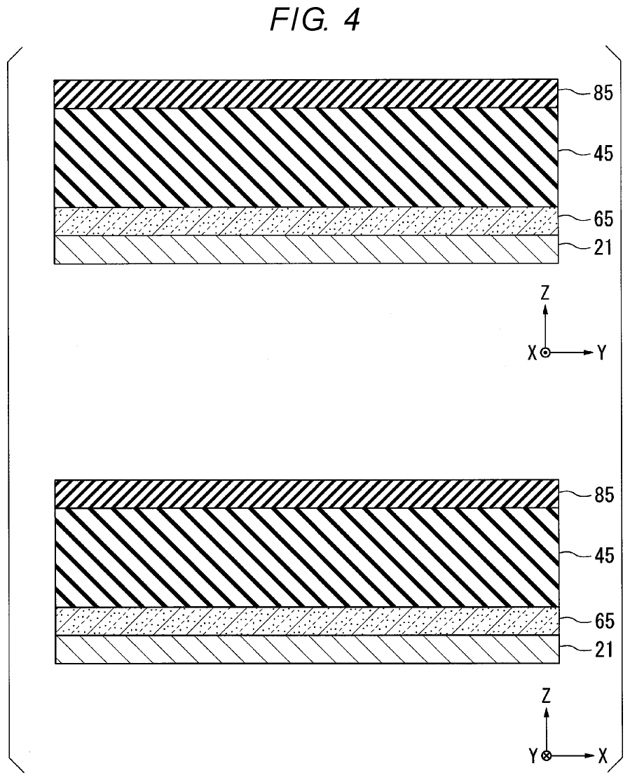

Next, a method for manufacturing a memory cell MC of the semiconductor storage device 1 will be briefly described. FIG. 4 shows an example of a manufacturing process of the memory cell MC, and is a cross-sectional view of a stacked body for forming the word line WL and the pillar 31. An upper part of each of FIGS. 4 to 15 is a cross-sectional view of components in each manufacturing process as viewed in the X direction. A lower part of each of FIGS. 4 to 15 is a cross-sectional view of components in each manufacturing process as viewed in the Y direction.

As shown in FIG. 4, a selector forming film 65, an insulating film 45, and an insulating film 85 are stacked in the Z direction on a first conductor 21 extending in the X direction and the Y direction. The first conductor 21 is, for example, tungsten (W). The insulating films 45 and 85 are formed of, for example, SiO₂.

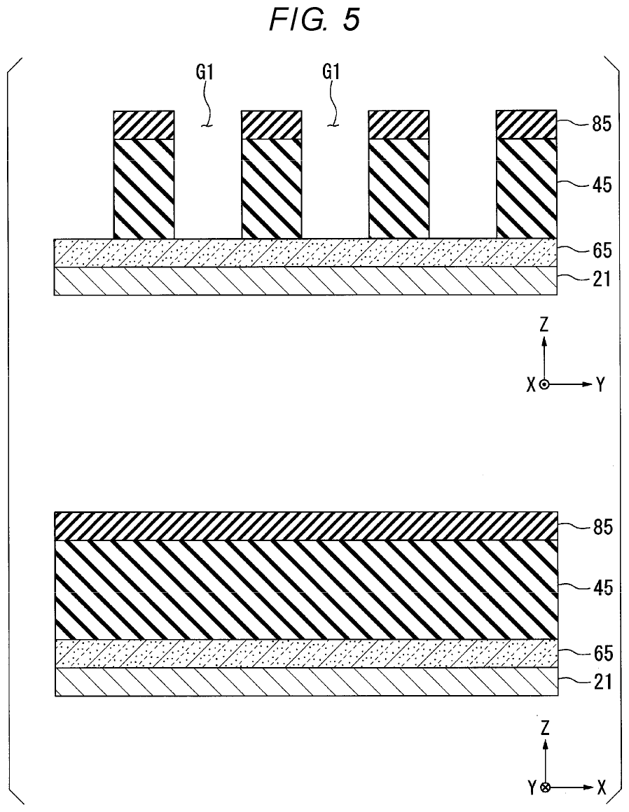

FIG. 5 shows an example of the manufacturing process of the memory cell MC, and is a cross-sectional view showing a groove forming process. For example, as shown in FIG. 5, by patterning, a plurality of grooves G1 are formed at predetermined intervals in the Y direction. The plurality of grooves G1 extend in the X direction and penetrate the insulating film 45 and the insulating film 85 in the Z direction. The insulating film 45 and the insulating film 85 are divided into a plurality of parts at intervals in the Y direction.

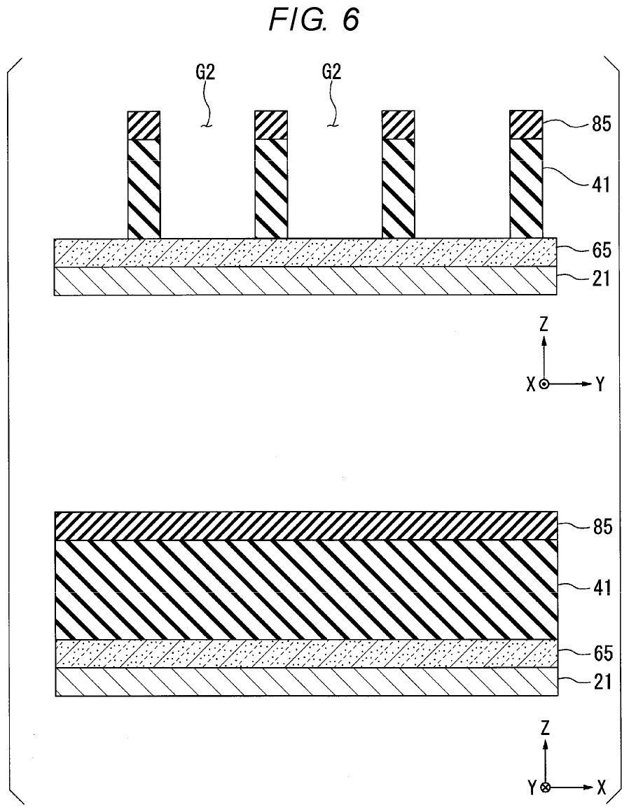

FIG. 6 shows an example of the manufacturing process of the memory cell MC, and is a cross-sectional view showing a slimming process. For example, as shown in FIG. 6, by using a chemical solution, the insulating films 45 and the insulating films 85 between the plurality of grooves G1 in the Y direction are slimmed. The grooves G1 expand to grooves G2 in the Y direction. At this time, a size of the insulating film 45 in the Y direction is made substantially equal to a design value of the size of the insulating film 45 in the Y direction in each memory cell MC of the semiconductor storage device 1. That is, the insulating film 41 of each memory cell MC is formed by slimming the insulating film 45.

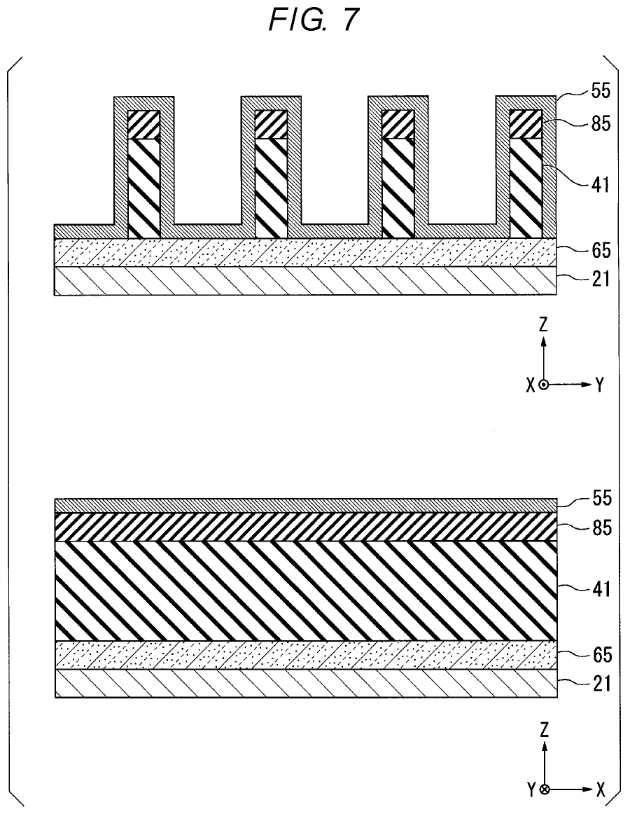

FIG. 7 shows an example of the manufacturing process of the memory cell MC, and is a cross-sectional view showing a PCM forming process. For example, as shown in FIG. 7, by an atomic layer deposition (ALD) method or a chemical vapor deposition (CVD) method, a variable resistance film forming film 55 having a predetermined thickness is formed on the selector forming film 65, the insulating film 41, and the insulating film 85 that are exposed when viewed from the Z direction. At this time, the predetermined thickness of the variable resistance film forming film 55 is made substantially equal to a design value of a size of the variable resistance film 51 in the Y direction in each memory cell MC of the semiconductor storage device 1.

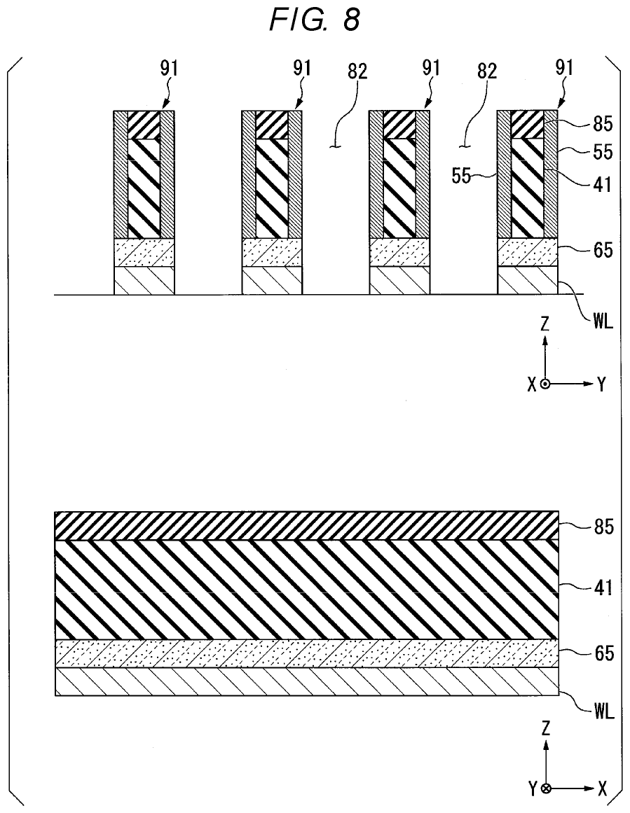

FIG. 8 shows an example of the manufacturing process of the memory cell MC, and is a cross-sectional view showing a word line forming process and a pillar forming process. For example, as shown in FIG. 8, by using dry etching, only the variable resistance film forming film 55 which is in contact with each side wall of the insulating film 41 and the insulating film 85 in the Y direction shown in FIG. 7 remains, and the other variable resistance film forming film 55, the exposed selector forming film 65 viewed from the Z direction, and the first conductor 21 overlapping the exposed selector forming film 65 in the Z direction are removed. The first conductor 21 is divided so that a remaining portion of the first conductor 21 becomes the word line WL. That is, the plurality of word lines WLs are formed at intervals in the Y direction. Simultaneously with the formation of the word lines WLs, a plurality of pillars 91 are formed with gaps 82 therebetween in the Y direction. The pillar 91 includes the selector forming film 65, the insulating film 41, the insulating film 85, and the variable resistance film forming film 55, and is in contact with the word line WL.

The selector forming film 65 of the pillar 91 has the same size as the word line WL in the Y direction. The insulating film 41 and the insulating film 85 of the pillar 91 are stacked at a center portion of the selector forming film 65 in the Y direction. The variable resistance film forming film 55 is stacked on the selector forming film 65 so as to be located on both sides of the insulating film 41 and the insulating film 85 in the Y direction. The selector forming film 65 and the insulating film 41 or the insulating film 85 and the variable resistance film forming films 55 on both sides in the Y direction have substantially the same size in the Y direction.

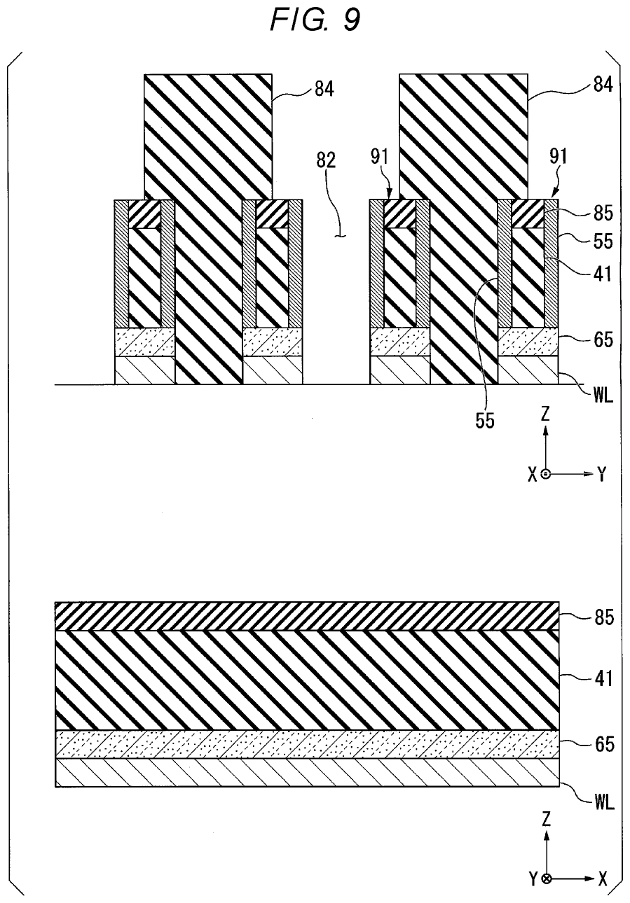

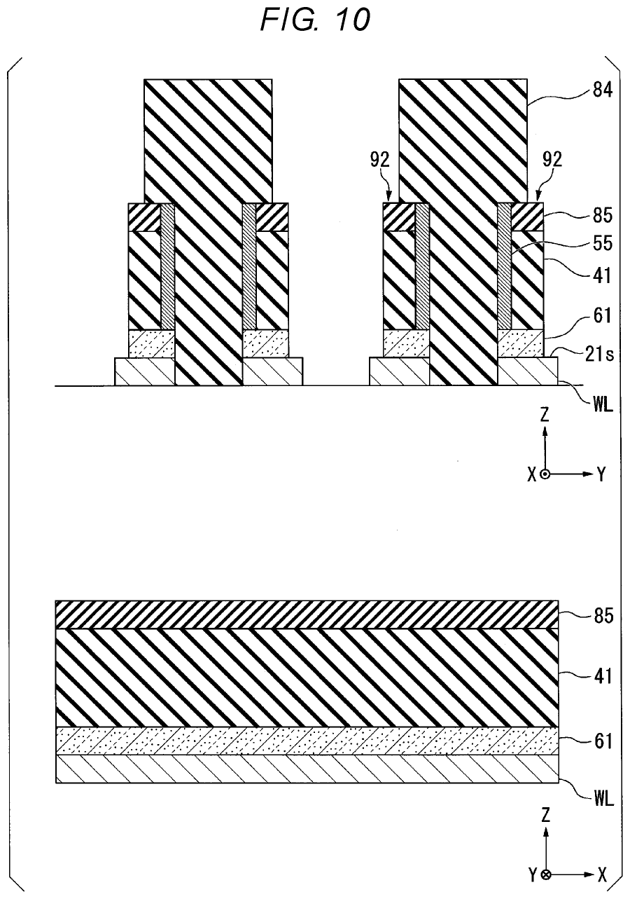

FIG. 9 shows an example of the manufacturing process of the memory cell MC, and is a cross-sectional view showing a resist forming process. For example, as shown in FIG. 9, by a photo engraving process (PEP), every other gap 82 in the Y direction is filled with a resist 84. The resist 84 is extended to substantially center portions in the Y direction of pillars 91 on both sides of the gap 82. At this time, a size of the resist 84 in the Z direction is larger than a size of the pillar 91 in the Z direction.

FIG. 10 shows an example of the manufacturing process of the memory cell MC, and is a cross-sectional view showing a variable resistance film removing process. For example, as shown in FIG. 9, by using a chemical solution, the variable resistance film forming film 55 that is exposed without being covered with the resist 84 and the selector forming film 65 that overlaps the exposed variable resistance film forming film 55 in the Z direction are removed. As shown in FIG. 10, by the variable resistance film portion removing process, one of the two variable resistance film forming films 55 disposed on each pillar 91 is removed so that a pillar 92 is formed. The selector forming film 65 that overlaps the exposed variable resistance film forming film 55 in the Z direction is removed so that a remaining portion becomes the selector film 61. A surface 21s at one end of the word line WL in the Y direction is exposed.

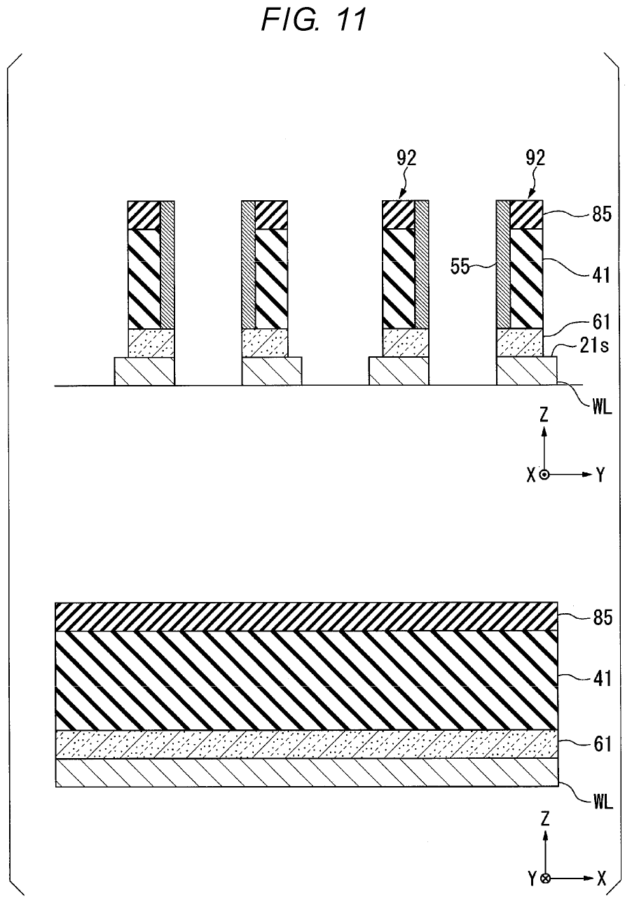

FIG. 11 shows an example of the manufacturing process of the memory cell MC, and is a cross-sectional view showing a resist removing process. For example, as shown in FIG. 11, the resist 84 is removed by using a chemical solution. In every other gap 82 in the Y direction, the variable resistance film forming films 55 of the adjacent pillars 92 face each other.

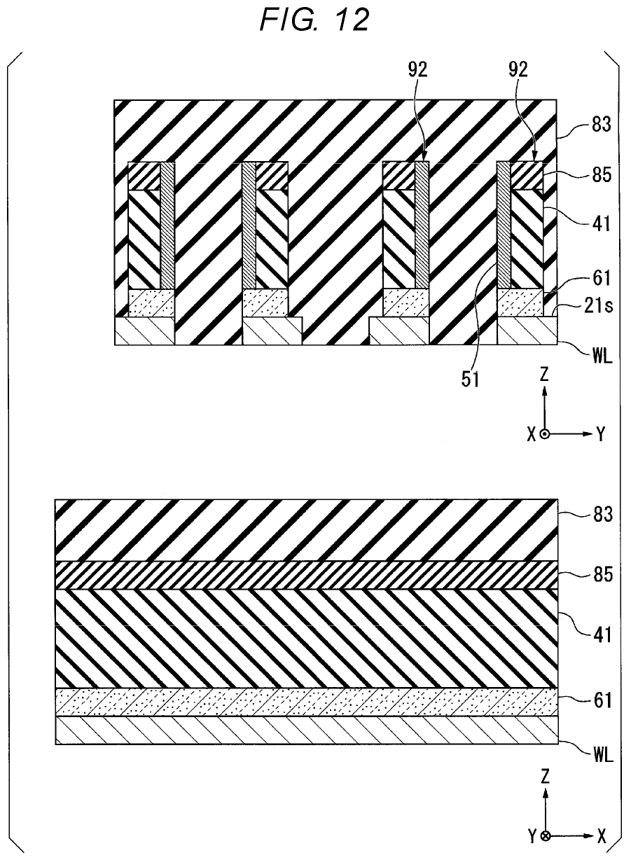

FIG. 12 shows an example of the manufacturing process of the memory cell MC, and is a cross-sectional view showing an interlayer insulating portion forming process. For example, as shown in FIG. 12, an insulating film 83 is stacked to fill the entire pillar 92 by the ALD method or the CVD method. The insulating film 83 is formed of the same material as the interlayer insulating portion 38 and the insulating portion 71, and is formed of, for example, SiO₂. At this time, a size of the insulating film 83 in the Z direction is larger than a size of the pillar 92 in the Z direction.

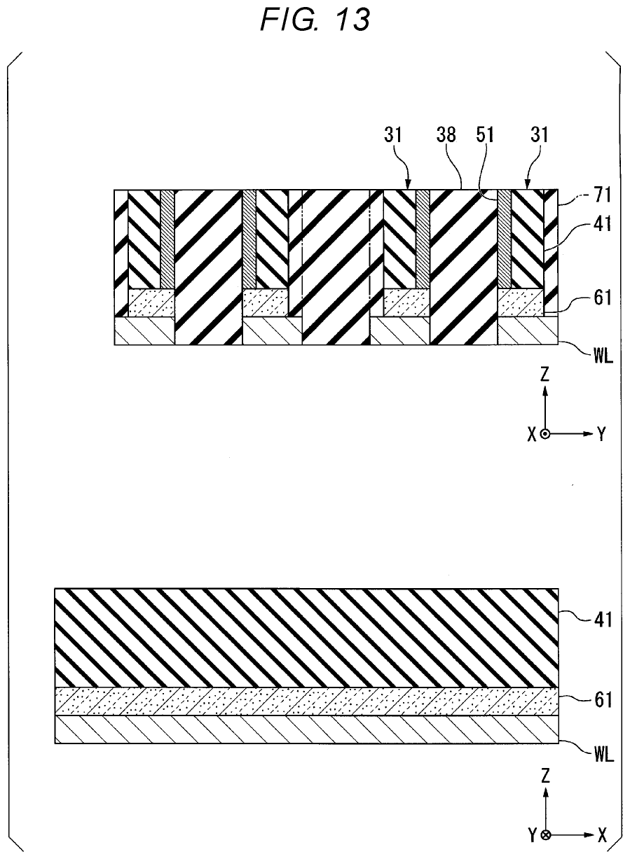

FIG. 13 shows an example of the manufacturing process of the memory cell MC, and is a cross-sectional view showing an interlayer insulating portion partially removing process. For example, as shown in FIG. 13, by chemical mechanical polishing (CMP), the insulating film 83, the insulating film 85, and the variable resistance film forming film 55 are polished and removed from a back side to a front side in the Z direction until the insulating portion 71 begins to be exposed. A remaining portion becomes the variable resistance film 51 by polishing and partially removing the variable resistance film forming film 55. By such an interlayer insulating layer partially removing process, a plurality of pillars 31 are formed at intervals at positions overlapping the word lines WLs in the Y direction, and the interlayer insulating portions 38 including the insulating portions 71 are interposed between the word lines WLs and the pillars 31 adjacent in the Y direction. As shown in FIG. 13, arrangements of the variable resistance film 51, the insulating film 41, and the selector film 61 of the plurality of pillars 31 adjacent in the Y direction are reversed to each other. End surfaces of the interlayer insulating portion 38, the insulating film 41, the variable resistance film 51, and the insulating portion 71 on a side opposite to the word line WL in the Z direction are aligned on the same plane, and are smooth with each other.

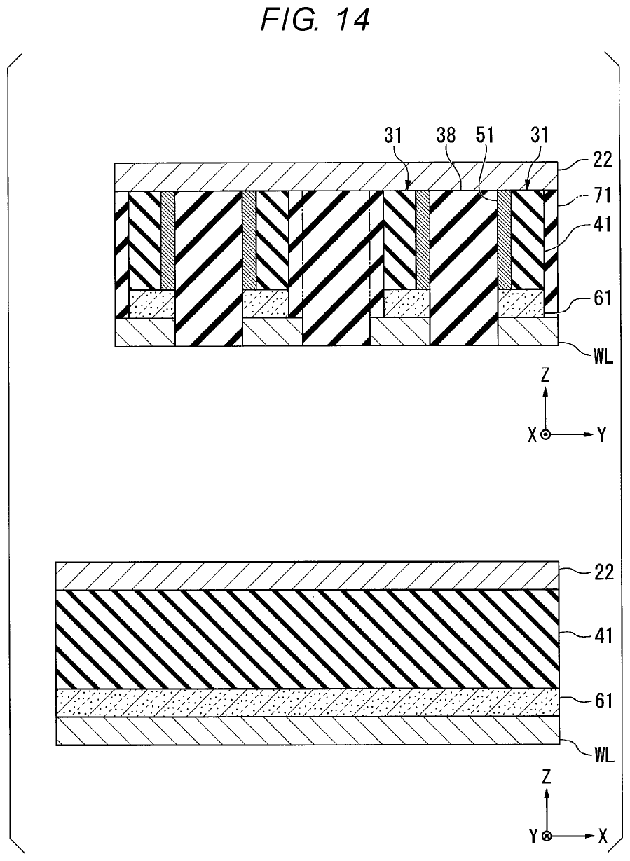

FIG. 14 shows an example of the manufacturing process of the memory cell MC, and is a cross-sectional view showing a second conductor forming process for forming the bit line BL. For example, as shown in FIG. 14, by a physical vapor deposition (PVD) method or the CVD method, a second conductor 22 is stacked on the end surfaces of the interlayer insulating portion 38, the insulating film 41, the variable resistance film 51, and the insulating portion 71 which are exposed when viewed from the Z direction. The second conductor 22 is, for example, tungsten (W).

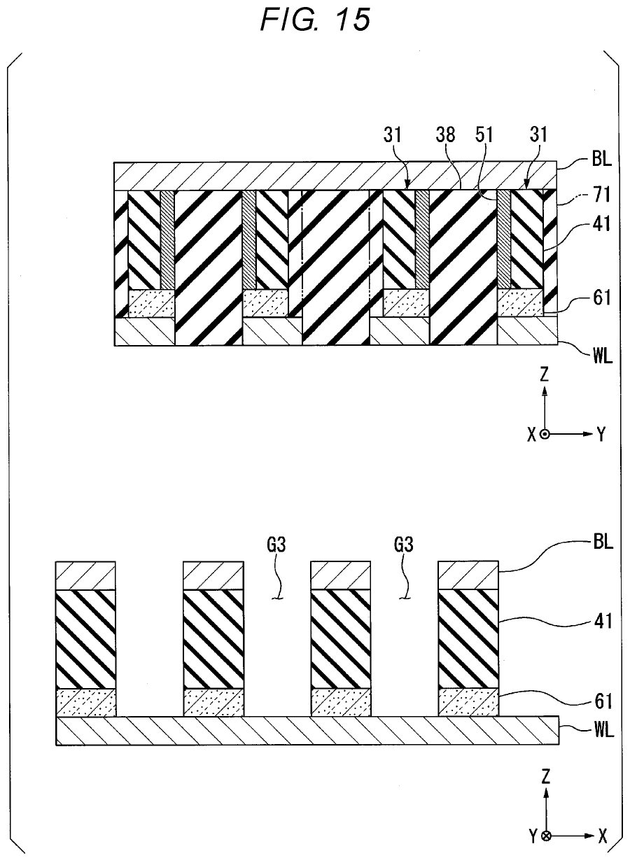

FIG. 15 shows an example of the manufacturing process of the memory cell MC, and is a cross-sectional view showing a bit line forming process. For example, as shown in FIG. 15, by patterning, a plurality of grooves G3 penetrating the insulating film 41 and the selector film 61 in the Z direction are formed at predetermined intervals in the X direction. By the bit line forming process, a plurality of bit lines BLs are formed at predetermined intervals in the X direction.

By performing the above-described processes, the memory cell MC shown in FIGS. 2 and 3 can be manufactured. The semiconductor storage device 1 is formed by performing known pretreatments before the above-described processes and performing known posttreatments after the above-described processes. However, a method of manufacturing the semiconductor storage device 1 is not limited to the above-described method.

Next, functions and effects of the semiconductor storage device 1 of the first embodiment described above will be described. According to the semiconductor storage device 1, when viewed from the Z direction, the variable resistance film 51 is disposed on one side of the insulating film 41 in the Y direction in the overlapping portion CP, that is, on the region of the first side, and on one side in the Y direction of the insulating portion 71. According to the semiconductor storage device 1, when viewed from the Z direction, the variable resistance film 51 is disposed only on a part of the overlapping portion CP. Accordingly, as compared to a case where the variable resistance film is disposed on both sides of the insulating film 41 or the insulating portion 71 in the Y direction or a case where the variable resistance film is disposed substantially over the entire overlapping portion CP as in a semiconductor storage device in the related art, a cross-sectional area of the variable resistance film 51 can be reduced. By reducing the cross-sectional area of the variable resistance film 51 viewed from the Z direction, a current density per portion area flowing through the variable resistance film 51, that is, the PCM, can be increased. Therefore, a reset current for changing the variable resistance film 51 from the low resistance state to the high resistance state in the semiconductor storage device 1 can be reduced. The reset current means a current value for raising a resistance of the variable resistance film 51 during the reset operation.

According to the semiconductor storage device 1, by forming the PCM of the memory cell MC as a sidewall of a sidewall process and forming the PCM on only one side of the pillar 31 in the Y direction, the cross-sectional area of the variable resistance film 51 can be reduced to be equal to or less than HP×HP, and the reset current can be reduced.

### Second Embodiment

Next, a configuration of a semiconductor storage device according to a second embodiment will be described. Although not shown, the semiconductor storage device according to the second embodiment is a so-called cross-point semiconductor storage device using a PCM similar to the semiconductor storage device 1 according to the first embodiment. The semiconductor storage device according to the second embodiment includes, for example, the silicon substrate 11, the interlayer insulating layer 12, a plurality of word lines WLs, a plurality of bit lines BLs, and a plurality of memory cells MCs. Hereafter, regarding components of the semiconductor storage device of the second embodiment, only contents different from the components of the semiconductor storage device 1 will be described, and detailed description of contents common to the components of the semiconductor storage device 1 will be omitted.

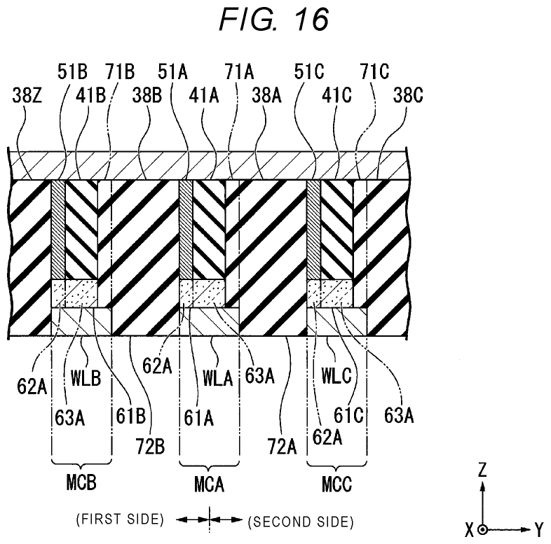

FIG. 16 is a cross-sectional view showing a plurality of the memory cells MCs arranged in a Y direction in the semiconductor storage device according to the second embodiment. As shown in FIG. 16, the first memory cell MCA includes, for example, the first insulating film 41A, the first variable resistance film 51A, the selector film 61A, and the first insulating portion 38A. The second memory cell MCB includes, for example, the second insulating film 41B, the second variable resistance film 51B, a selector film 61B, and the second insulating portion 38B. The third memory cell MCC includes, for example, the third insulating film 41C, the third variable resistance film 51C, a selector film 61C, and a third insulating portion 38C.

In the semiconductor storage device according to the second embodiment, the first variable resistance film 51A is disposed at a position shifted to a first side in the Y direction with respect to a center portion of the word line WLA in the Y direction. The second variable resistance film 51B is disposed at a position shifted to the first side in the Y direction with respect to a center portion of the word line WLB in the Y direction. That is, the first variable resistance film 51A and the second variable resistance film 51B are respectively disposed at positions shifted to the first side with respect to the center portion of the word line WLA and the center portion of the word line WLB in the Y direction.

The second insulating portion 38B includes an insulating portion 71B provided between the bit line BL and the word line WLB in the Z direction. The second insulating portion 38B is in contact with the first variable resistance film 51A from a side opposite to the first insulating film 41A. That is, the second insulating portion 38B is adjacent to the first variable resistance film 51A from the first side in the Y direction. The insulating portion 71B is adjacent to the selector film 61B in the Y direction. The insulating portion 71B is an example of “a part of a second insulating portion.” The second insulating portion 38B is provided between the first insulating film 41A and the second insulating film 41B in the Y direction. The second insulating portion 38B is an example of “an insulating portion provided between a first insulating film and a second insulating film in a first direction.”

Next, a method for manufacturing a memory cell MC of the semiconductor storage device according to the second embodiment will be briefly described. The memory cell MC of the semiconductor storage device according to the second embodiment can be manufactured by performing similar processes as the method for manufacturing the semiconductor storage device 1 except for a resist forming process. In manufacturing of the semiconductor storage device 1, in the resist forming process described with reference to FIG. 9, every other gap 82 in the Y direction is filled with the resist 84, and the resist 84 is extended to a substantially center portion in the Y direction of the pillars 91 on both sides of the gap 82. Therefore, by a variable resistance film removing process and a resist removing process, the variable resistance films 51 of the pillars 92 adjacent to each other in every other gap 82 in the Y direction are formed at relative positions facing each other. With such a manufacturing method, the number of the resists 84 to be formed can be reduced and the resist forming process can be easily performed.

When the memory cell MC of the semiconductor storage device according to the second embodiment is manufactured, in the resist forming process, for example, only the same side from a center of all the gaps 82 in the Y direction is filled with the resist 84, and the resist 84 is extended to a substantially center portion in the Y direction of the pillars on the same side in the Y direction. Hereafter, by performing a variable resistance film partially removing process, the resist removing process, and an interlayer insulating layer removing process, as shown in FIG. 16, the variable resistance films 51, the insulating films 41, and the insulating portions 71 of a plurality of pillars 31 can be aligned with each other in the Y direction. That is, relative arrangements of the second variable resistance film 51B, the second insulating film 41B, and the insulating portion 71B of the second memory cell MCB are the same as relative arrangements of the first variable resistance film 51A, the first insulating film 41A, and the insulating portion 71A of the first memory cell MCA. Relative arrangements of the third variable resistance film 51C, the third insulating film 41C, and the insulating portion 71C of the third memory cell MCC are the same as the relative arrangements of the first variable resistance film 51A, the first insulating film 41A, and the insulating portion 71A of the first memory cell MCA.

The semiconductor storage device according to the second embodiment has a similar configuration as the semiconductor storage device 1 according to the first embodiment, so that a reset current can be reduced. According to the semiconductor storage device according to the second embodiment, phase change characteristics of the plurality of pillars 31 can be made uniform. According to the semiconductor storage device according to the second embodiment, distances between the variable resistance films 51 can be substantially the same in the Y direction. Accordingly, since the variable resistance films 51 do not generate portions that are close to each other in the Y direction, it is possible to prevent a thermal influence of one memory cell MC from adjacent memory cells MCs as compared to the first embodiment.

While certain embodiments have been described, these embodiments have been presented by way of example only, and are not intended to limit the scope of the claims. Indeed, the novel embodiments described herein may be embodied in a variety of other forms; furthermore, various omissions, substitutions and changes in the form of the embodiments described herein may be made without departing from the spirit of the claimed inventions. The accompanying claims and their equivalents are intended to cover such forms or modifications as would fall within the scope and spirit of the claimed inventions.

For example, in each of the embodiments described above, the variable resistance film 51 is disposed on the first side from a center of the overlapping portion CP in the Y direction when viewed from the Z direction. However, the variable resistance film 51 may be disposed over an entire region on the first side of the insulating portion 71 in the Y direction and overlapped with the overlapping portion CP when viewed from the Z direction. Further, the variable resistance film 51 may overlap only a part of the overlapping portion CP in the X direction when viewed in the Z direction.

Hereinafter, characteristics of the semiconductor storage device will be additionally described.

[1]A semiconductor storage device includes:

a first wiring extending in a first direction;

a second wiring extending in a second direction intersecting the first direction and provided at a position different from the first wiring in a third direction intersecting the first direction and the second direction;

a first insulating film provided between the first wiring and the second wiring in the third direction;

a first variable resistance film provided between the first wiring and the second wiring in the third direction, and adjacent to the first insulating film in the first direction; and

a first insulating portion that includes a portion provided between the first wiring and the second wiring in the third direction and is adjacent to the first insulating film from a side opposite to the first variable resistance film.

[2]. The semiconductor storage device according to [1], in which

the first variable resistance film is disposed at a position shifted in the first direction with respect to a center of the second wiring in the first direction.

[3]. The semiconductor storage device according to [2], in which

the first variable resistance film is disposed between the center of the second wiring in the first direction and an edge of the second wiring in the first direction.

[4]. The semiconductor storage device according to [1], in which

the first variable resistance film is in contact with the first insulating film in the first direction.

[5]. The semiconductor storage device according to [1], in which

the first insulating portion is in contact with the first insulating film from the side opposite to the first variable resistance film.

[6]. The semiconductor storage device according to [1], in which

a maximum thickness of the first variable resistance film in the first direction is smaller than a maximum thickness of the first insulating film in the first direction.

[7]. The semiconductor storage device according to [1], in which

a maximum thickness of the first variable resistance film in the first direction is equal to or less than half a maximum width of the second wiring in the first direction.

[8]. The semiconductor storage device according to [1], in which

a length of the first variable resistance film in the third direction is larger than maximum thicknesses of the first variable resistance film in the first direction and the second direction.

[9]. The semiconductor storage device according to [1], in which

a length of the first insulating film in the third direction is larger than maximum thicknesses of the first insulating film in the first direction and the second direction.

[10]. The semiconductor storage device according to [1], further includes:

a selector film including a first portion provided between one of the first wiring and the second wiring and the first variable resistance film in the third direction, and a second portion provided between the one of the first wiring and the second wiring in the third direction and the first insulating film in the third direction.

[11]. The semiconductor storage device according to [10], in which

a part of the first insulating portion is adjacent to the selector film in the first direction.

[12]. The semiconductor storage device according to [10], in which

a maximum thickness of the first variable resistance film in the first direction is smaller than a maximum thickness of the selector film in the third direction.

[13]. The semiconductor storage device according to [10], in which

a maximum thickness of the first insulating film in the first direction is smaller than a maximum thickness of the selector film in the third direction.

[14]. The semiconductor storage device according to [1], further includes:

a third wiring adjacent to the second wiring in the first direction and extending in the second direction;

a second insulating film provided between the first wiring and the third wiring in the third direction;

a second variable resistance film provided between the first wiring and the third wiring in the third direction, and adjacent to the second insulating film in the first direction; and

a second insulating portion adjacent to the second insulating film from a side opposite to the second variable resistance film.

[15]. The semiconductor storage device according to [14], in which

the first variable resistance film is disposed at a position shifted to a first side in the first direction with respect to a center portion of the second wiring in the first direction, and

the second variable resistance film is disposed at a position shifted to a second side which is opposite to the first side in the first direction with respect to a center portion of the third wiring in the first direction.

[16]. The semiconductor storage device according to [15], further includes:

a fourth wiring adjacent to the second wiring from a side opposite to the third wiring in the first direction and extending in the second direction;

a third insulating film provided between the first wiring and the fourth wiring in the third direction; and

a third variable resistance film provided between the first wiring and the fourth wiring in the third direction, and adjacent to the third insulating film in the first direction, in which

the first insulating portion includes a portion provided between the first wiring and the fourth wiring in the third direction.

[17]. The semiconductor storage device according to [14], in which

the first variable resistance film is disposed at a position shifted to a first side in the first direction with respect to a center portion of the second wiring in the first direction, and

the second variable resistance film is disposed at a position shifted to the first side in the first direction with respect to a center portion of the third wiring in the first direction.

[18]. The semiconductor storage device according to [16], in which

the second insulating portion includes a portion provided between the first wiring and the third wiring in the third direction.

[19]. The semiconductor storage device according to [16], in which

the second insulating portion is in contact with the first variable resistance film from a side opposite to the first insulating film.

[20]. The semiconductor storage device according to [16], in which

a part of the second insulating portion is provided between the second wiring and the third wiring in the first direction.

[21]A semiconductor storage device includes:

a first wiring extending in a first direction;

a second wiring extending in a second direction intersecting the first direction and provided at a position different from the first wiring in a third direction intersecting the first direction and the second direction;

a first insulating film provided between the first wiring and the second wiring in the third direction;

a first variable resistance film provided between the first wiring and the second wiring in the third direction, and adjacent to the first insulating film in the first direction;

a third wiring adjacent to the second wiring in the first direction and extending in the second direction;

a second insulating film provided between the first wiring and the third wiring in the third direction;

a second variable resistance film provided between the first wiring and the third wiring in the third direction, and adjacent to the second insulating film in the first direction; and

an insulating portion that includes a portion provided between the first wiring and the third wiring in the third direction, and is provided between the first insulating film and the second insulating film in the first direction.

What is claimed is:

1. A semiconductor storage device comprising:
a first wiring extending in a first direction;
a second wiring extending in a second direction intersecting the first direction and provided at a position different from the first wiring in a third direction, the third direction intersecting the first direction and the second direction;
a first insulating film provided between the first wiring and the second wiring in the third direction;
a first variable resistance film provided between the first wiring and the second wiring in the third direction and adjacent to the first insulating film in the first direction; and
a first insulating portion that includes a portion provided between the first wiring and the second wiring in the third direction and is adjacent to the first insulating film from a side opposite to the first variable resistance film in the first direction.

2. The semiconductor storage device according to the claim 1, wherein
the first variable resistance film is disposed at a position shifted in the first direction with respect to a center portion of the second wiring in the first direction.

3. The semiconductor storage device according to claim 2, wherein
in the first direction, the first variable resistance film is disposed between the center of the second wiring and an edge of the second wiring.

4. The semiconductor storage device according to claim 1, wherein
the first variable resistance film is in contact with the first insulating film.

5. The semiconductor storage device according to claim 1, wherein
the first insulating portion is in contact with the first insulating film from the side opposite to the variable resistance film.

6. The semiconductor storage device according to claim 1, wherein
a maximum thickness of the first variable resistance film in the first direction is smaller than a maximum thickness of the first insulating film in the first direction.

7. The semiconductor storage device according to claim 1, wherein
a maximum thickness of the first variable resistance film in the first direction is equal to or less than half a maximum width of the second wiring in the first direction.

8. The semiconductor storage device according to claim 1, wherein
a length of the first variable resistance film in the third direction is larger than a maximum thicknesses of the first variable resistance film in the first direction and the second direction.

9. The semiconductor storage device according to claim 1, wherein
a length of the first insulating film in the third direction is larger than a maximum thicknesses of the first insulating film in the first direction and the second direction.

10. The semiconductor storage device according to claim 1, further comprising:
a selector film including a first portion provided between one of the first wiring and the second wiring and the first variable resistance film in the third direction, and a second portion provided between the one of the first wiring and the second wiring in the third direction and the first insulating film in the third direction.

11. The semiconductor storage device according to claim 10, wherein
a part of the first insulating portion is adjacent to the selector film in the first direction.

12. The semiconductor storage device according to claim 10, wherein
a maximum thickness of the first variable resistance film in the first direction is smaller than a maximum thickness of the selector film in the third direction.

13. The semiconductor storage device according to claim 10, wherein
a maximum thickness of the first insulating film in the first direction is smaller than a maximum thickness of the selector film in the third direction.

14. The semiconductor storage device according to claim 1, further comprising:
a third wiring adjacent to the second wiring in the first direction and extending in the second direction;
a second insulating film provided between the first wiring and the third wiring in the third direction;
a second variable resistance film provided between the first wiring and the third wiring in the third direction, and adjacent to the second insulating film in the first direction; and
a second insulating portion adjacent to the second insulating film from a side opposite to the second variable resistance film.

15. The semiconductor storage device according to claim 14, wherein
the first variable resistance film is disposed at a position shifted to a first side in the first direction with respect to a center portion of the second wiring in the first direction, and
the second variable resistance film is disposed at a position shifted to a second side which is opposite to the first side in the first direction with respect to a center portion of the third wiring in the first direction.

16. The semiconductor storage device according to claim 15, further comprising:
a fourth wiring adjacent to the second wiring from a side opposite to the third wiring in the first direction and extending in the second direction;
a third insulating film provided between the first wiring and the fourth wiring in the third direction; and
a third variable resistance film provided between the first wiring and the fourth wiring in the third direction, and adjacent to the third insulating film in the first direction, wherein
the first insulating portion includes a portion provided between the first wiring and the fourth wiring in the third direction.

17. The semiconductor storage device according to claim 14, wherein
the first variable resistance film is disposed at a position shifted to a first side in the first direction with respect to a center portion of the second wiring in the first direction, and
the second variable resistance film is disposed at a position shifted to the first side in the first direction with respect to a center portion of the third wiring in the first direction.

18. The semiconductor storage device according to claim 16, wherein
the second insulating portion includes a portion provided between the first wiring and the third wiring in the third direction.

19. The semiconductor storage device according to claim 16, wherein
the second insulating portion is in contact with the first variable resistance film from a side opposite to the first insulating film.

20. A semiconductor storage device comprising:
a first wiring extending in a first direction;
a second wiring extending in a second direction intersecting the first direction and provided at a position different from the first wiring in a third direction, the third direction intersecting the first direction and the second direction;
a first insulating film provided between the first wiring and the second wiring in the third direction;
a first variable resistance film provided between the first wiring and the second wiring in the third direction, and adjacent to the first insulating film in the first direction;
a third wiring adjacent to the second wiring in the first direction and extending in the second direction;
a second insulating film provided between the first wiring and the third wiring in the third direction;
a second variable resistance film provided between the first wiring and the third wiring in the third direction, and adjacent to the second insulating film in the first direction; and
an insulating portion that includes a portion provided between the first wiring and the second wiring in the third direction, and is provided between the first insulating film and the second insulating film in the first direction.
